(19) United States
(12) Patent Application Publication
(10) Pub. No.: US 2022/0205136 A1
(43) Pub. Date: Jun. 30, 2022

(54) CRYSTAL GROWTH METHOD AND CRYSTAL GROWTH APPARATUS

(71) Applicant: Zing Semiconductor Corporation, Shanghai (CN)

(72) Inventors: Weimin SHEN, Shanghai (CN); Youshu LEI, Shanghai (CN)

(73) Assignee: Zing Semiconductor Corporation, Shanghai (CN)

(21) Appl. No.: 17/196,288

(22) Filed: Mar. 9, 2021

(30) Foreign Application Priority Data
Dec. 30, 2020 (CN) 202011611880.8

(51) Int. Cl. C30B 30/04; C30B 15/10; C30B 15/14; C30B 15/20; C30B 15/30; C30B 29/06

(52) U.S. Cl. CPC C30B 30/04; C30B 15/10; C30B 29/06; C30B 15/206; C30B 15/30; C30B 15/14

(57) ABSTRACT

A crystal growth method and a crystal growth apparatus are disclosed in the present application. The crystal growth method comprises maintaining rotating of a crucible and meanwhile applying a horizontal magnetic field to silicon melt in the crucible during crystal growth. As and/or after changing magnetic field strength of the horizontal magnetic field, temperature fluctuation may easily occur at a solid-liquid interface of an ingot and the silicon melt. Through changing crucible rotating speed to change forced convection of the silicon melt, the temperature fluctuation at solid-liquid interface, caused by the changing of the magnetic field strength, may be rapidly reduced to stabilize diameter of the ingot.

### FIELD OF THE INVENTION

The present invention generally relates to semiconductors, and specifically, to a crystal growth method and a crystal growth apparatus.

### BACKGROUND OF THE INVENTION

Czochralski method (CZ method) is an important technology to obtain single crystals of silicon for semiconductors and solar cells. An ingot may be made through heating and melting high-purity silicon material with thermal field of carbon material, and then a series of processes (dissolution, temperature stabilization, dipping seed crystal, shouldering, cylindrical growth, growth of end cone, cooling down).

Temperature distribution of the ingot and silicon melt directly affects quality and growing rate of the ingot during the growth of ingot with CZ method for single crystals applied in semiconductor or solar energy industries. Thermal convection in the silicon melt makes micro-impurities uneven and so as to form growth striations during the growth of ingot. Therefore, in crystal pulling process, how to inhibit thermal convection and temperature fluctuation draws people's attention.

Magnetic Czochralski (MCZ) technology, performed with a magnetic field generator, creates magnetic field on silicon melt, served as conductor, to apply Lorentz force which direction is opposite to the motion of the silicon melt to the silicon melt, so as to inhibit the convection in the silicon melt, increase viscosity of the silicon melt, and reduce entrance of impurities from the quartz crucible, such as oxygen, carbon, aluminum, into the silicon melt and further the ingot. Eventually, oxygen content of the grown ingot may be controlled within a wide range from low to high to diminish the growth striations. Therefore, MCZ technology is popular. A typical MCZ technology, called Horizontal Magnetic Czochralski (HMCZ) technology, applying horizontal magnetic field to the silicon melt in the crucible, is broadly used for growing an ingot with high diameter and high quality.

Strong magnetic field, mainly applied in the temperature stabilization process, is generated by charging outer magnet around a main furnace with electricity during the temperature stabilization process. Then, the magnetic field is applied to the silicon melt in the crucible inside the furnace and then adjusted to adapt for ingot growth. However, because it is necessary to change the magnetic field strength during the ingot growth, for example, raising from 1500 G to 4000 G, the changing of the magnetic field strength makes convection velocity of the silicon melt of silicon in the crucible complex. Usually, in a period after changing the magnetic field strength, it is relatively hard to control ingot's diameter. Therefore, oftentimes it can be seen that the diameter varies periodically.

To solve current problem(s), the present invention provides a crystal growth method and a crystal growth apparatus.

### SUMMARY OF THE INVENTION

A series of simplified concepts are introduced in the summary of the invention paragraphs. Details will be further illustrated in embodiments. It is not intended to define key and essential feature(s) of technical schemes seeking protection, nor to confirm claimed scopes here.

To solve current problem(s), the present invention provides a crystal growth method comprising a step of maintaining rotating of a crucible and meanwhile applying a horizontal magnetic field to silicon melt in the crucible during crystal growth, wherein as and/or after a magnetic field strength of the horizontal magnetic field is changed, crucible rotating speed is changed.

Exemplarily, after the horizontal magnetic field is changed and as a diameter of an ingot obtained from crystal growth changes, the crucible rotating speed may be changed.

Exemplarily, as and/or after the magnetic field strength of the horizontal magnetic field is increased, increasing the crucible rotating speed may be performed.

Exemplarily, the crucible rotating speed changing may be periodic.

Exemplarily, during each period of the crucible rotating speed changing, the method of the crucible rotating speed changing may comprise: increasing the crucible rotating speed from R0 to R1; maintaining the crucible rotating speed at R1 for a while; and decreasing the crucible rotating speed from R1 to R0, wherein R0 is an initial crucible rotating speed.

Exemplarily, the crucible rotating speed from R0 to R1 may be increased linearly, and/or the crucible rotating speed from R1 to R0 may be decreased linearly.

Exemplarily, during the crucible rotating speed being changed periodically, a time interval may exist between two consecutive periods.

Exemplarily, during the period of the crucible rotating speed periodically changing, the crucible rotating speed changing times is no less than 10.

The present invention further provides a crystal growth apparatus, comprising: a crucible, containing silicon melt; a pulling device, pulling the silicon melt to form an ingot; a magnetic field applying device, applying a horizontal magnetic field to the silicon melt in the crucible and adjusting magnetic field strength of the magnetic field; a driving device, driving rotating of the crucible; and a controlling device, configured to perform the steps as illustrated in the above-mentioned crystal growth method.

Exemplarily, a diameter detector detecting a diameter of the ingot may be further comprised.

According to the crystal growth method and crystal growth apparatus of the present invention, during the crystal growth, horizontal magnetic field is applied to the silicon melt in the crucible, and as and/or after a magnetic field strength of the horizontal magnetic field is changed, crucible rotating speed is changed. Because temperature fluctuation may easily occur at solid-liquid interface of an ingot and the silicon melt as and/or after adjusting magnetic field strength of the horizontal magnetic field, through crucible rotating speed changing to change forced convection of the silicon melt, the temperature fluctuation at solid-liquid interface, caused by the changing of the magnetic field strength, may be rapidly reduced to stabilize diameter of the ingot.

### BRIEF DESCRIPTION OF THE DRAWINGS

Various objects and advantages of the present invention will be more readily understood from the following detailed description when read in conjunction with the appended drawing, in which:

FIG. 1 shows a structural perspective view of a crystal growth apparatus according to an embodiment of the present invention;

FIG. 2 shows a perspective view of convection in silicon melt at solid-liquid interface of an ingot and the silicon melt according to an embodiment of a crystal growth method of the present invention;

FIG. 3 shows a plot diagram of variation of temperature of the silicon melt at the solid-liquid interface of the ingot and the silicon melt along with time according to an embodiment of a crystal growth method of the present invention;

FIG. 4 shows a plot diagram of variation of crucible rotating speed along with time according to an embodiment of the present invention.

### DESCRIPTION OF EMBODIMENTS OF THE INVENTION

Example embodiments are provided so that this disclosure will be thorough, and will fully understand the present application to person skilled in the art. However, it will be apparent to the person skilled in the art that specific detail(s) need not be implemented. In some example embodiments, well-known features may not be described.

For a thorough understanding of the present invention, the details will be set forth in the following description in order to explain crystal growth methods of the present invention. Preferred embodiments of the present invention are described in detail as follows, however, in addition to the detailed description, the present invention also may be implemented in other ways.

The terminology used here is for the purpose of describing particular embodiments only and is not intended to limit the present application. Singular forms of “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups. It is also to be understood that “and/or” includes all combinations of associated steps or elements.

Now, the present invention will be more readily understood from the following detailed description when read in conjunction with the appended drawing. It should be understood that the embodiments disclosed here may be practiced in different forms and that neither should be construed to limit the claimed scope. On the contrary, the examples are provided to achieve a full and complete disclosure and make the person skilled in the art fully contain the idea of the embodiments. In the drawings, for clarity purpose, the size and the relative size of layers and areas may be exaggerated, and same reference number indicates same element.

### Embodiment 1

To solve current problem(s), the present invention provides a crystal growth method comprising a step of maintaining rotating of a crucible and meanwhile applying a horizontal magnetic field to silicon melt in the crucible during crystal growth, wherein as and/or after a magnetic field strength of the horizontal magnetic field is adjusted, crucible rotating speed is changed.

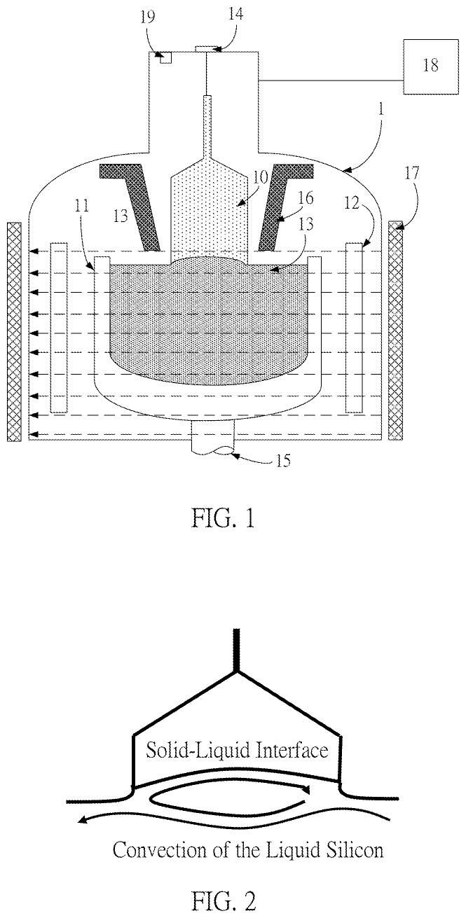

Referring to FIG. 1 showing a structural perspective view of a crystal growth apparatus according to an embodiment of the present invention, the growth apparatus comprises a furnace 1 inside of which a crucible is positioned. A heater 12 heating the crucible 11 is positioned outside the crucible 11. Silicon melt 13 is contained in the crucible 11.

Exemplarily, the crucible 11 is constructed by a graphite crucible and a quartz crucible set in the graphite crucible. The graphite crucible may be heated by the heater 12 to melt polysilicon material to form the silicon melt 13.

Referring to FIG. 1, the crystal growth apparatus according to the present invention comprises a pulling device 14 positioned at the top of the furnace 1. Driven by the pulling device 14, a crystal seed pulls an ingot 10 out of a fluid level of the silicon melt 13. Meanwhile, a heating screen is positioned around the ingot 10. As shown in FIG. 1, the heating screen may exemplarily comprise a draft tube 16 of barrel shape. On one hand, the draft tube 16 may isolate a surface of the ingot 10 from thermal radiations generated by the quartz crucible and the silicon melt 13, and increase cooling speed and axial temperature gradient of the ingot 10 to raise growth speed of the ingot 10. On the other hand, the heating screen may affect thermal field distribution of a surface of the silicon melt 13 to avoid from excessive difference of the axial temperature gradient between a center and a rim of the ingot 10, and ensure stable growth at an interface of the ingot 10 and the silicon melt 13. Meanwhile, the draft tube 16 may be used to pipeline inert gas introduced from the upper portion of the furnace 1. Then, the inert gas may pass the surface of the silicon melt 13 with a greater speed to control oxygen and impurity content in the ingot 10. During the growth of the ingot 10, moving with the pulling device 14, the ingot 10 moves upward and vertically, and passes through the draft tube 16.

To stabilize the growth of the ingot 10, a driving device 15 driving rotating of the crucible 11 is positioned at the bottom portion of the furnace 1. The driving device 15 drives the crucible 11 keep rotating during crystal pulling may reduce thermal asymmetry of the silicon melt 13 to grow the ingot 10 with a constant diameter.

To inhibit convection of the silicon melt 13, viscosity of the silicon melt 13 may be increased, and entrance of impurities from the quartz crucible, such as oxygen, carbon, aluminum, into the silicon melt 13 and further into the ingot may be reduced. Eventually, oxygen content of the grown ingot 10 may be controlled within a wide range from low to high to diminish growth striations. The crystal growth apparatus may further comprise a magnetic field applying device 17 to apply magnetic field to the silicon melt 13 in the crucible 11.

Magnetic field lines of the magnetic field applied by the magnetic field applying device 17 horizontally start from one end, pass the silicon melt 13 in the crucible 11, and then arrive an opposite end (referring to an arrow in dashed line in FIG. 1). Because the silicon melt 13 in fluid status has electric conductivity, under the magnetic field, Lorentz force generated in the silicon melt 13 inhibits natural convection in the silicon melt 13, which affects the diameter of the ingot 10 significantly.

Referring to FIG. 2, which shows a perspective view of convection in silicon melt at solid-liquid interface of an ingot and the silicon melt according to an embodiment of a crystal growth method of the present invention. Because the convection at the solid-liquid interface is affected relatively significantly by the magnetic field strength, it can be seen that the convection in the silicon melt 13 at the solid-liquid interface of an ingot and the silicon melt changes when magnetic field strength is changed and uneven temperature at the fluid level of the silicon melt 13 and inside the silicon melt 13. Temperature fluctuation occurs at the fluid level of the silicon melt 13 underneath the solid-liquid interface and so as to affect the diameter of the ingot 10. Along major axis of the ingot 10, the diameter varies.

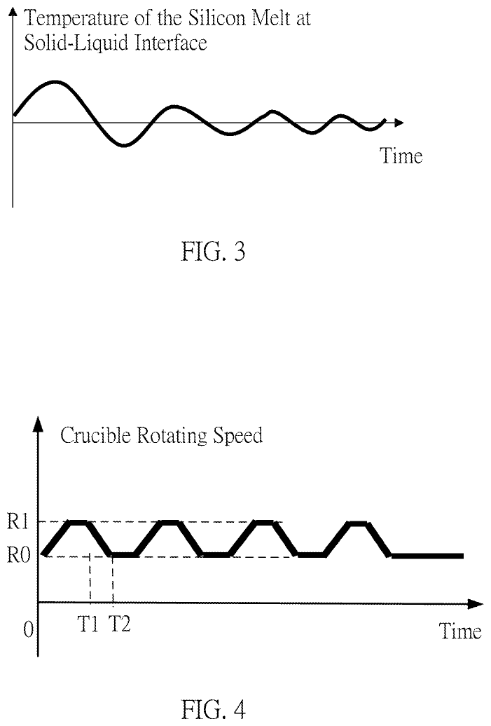

As shown in FIG. 3, which shows a plot diagram of variation of temperature of the silicon melt at the solid-liquid interface of the ingot and the silicon melt along with time according to an embodiment of a crystal growth method of the present invention, temperature changes periodically at the fluid level of the silicon melt 13 underneath the solid-liquid interface. In FIG. 3, vertical axis represents the temperature of the silicon melt 13 at the fluid level, and horizontal axis represents time. It can be seen that when the magnetic field strength of the horizontal magnetic field in the silicon melt 13 changes, the temperature of the silicon melt 13 underneath the solid-liquid interface periodically fluctuates along with time, and amplitude of the fluctuation decreases when time increases.

Specifically, in an example, the magnetic field may be increased from 1500 G to 4000 G and the crucible rotating speed 11 may be kept at 0.5 RPM according to technical requirements to form an ingot with a target diameter of 305 mm. When the magnetic field changes, the diameter of the ingot changes. Specifically, the diameter of the ingot changes within +/−2.0 mm, and periodically fluctuation of the ingot's diameter occurs. The fluctuation may not be stable until the diameter reaches 300 mm.

To solve current problem(s), the present invention provides a crystal growth method; specifically, rotating of a crucible receiving silicon melt is maintained and meanwhile a horizontal magnetic field is applied to the silicon melt in the crucible during crystal growth. As and/or after a magnetic field strength of the horizontal magnetic field is adjusted, crucible rotating speed is changed.

Because convection of the silicon melt, especially that at fluid level of the silicon melt, changes, generated by changed magnetic field strength of horizontal magnetic field applied to the silicon melt, temperature fluctuation occurs and then the diameter of the ingot changes. As and/or after adjusting magnetic field strength of the horizontal magnetic field applied to the silicon melt, through crucible rotating speed changing to change convection of the silicon melt, it may reduce the effect of the change of the magnetic field strength of the magnetic field on the convection of the silicon melt, and then avoid from temperature change at the fluid level of the silicon melt.

When the horizontal magnetic field changes, the change of the convection intensity of the silicon melt generated consequently will not affect the temperature of the fluid level of the silicon melt immediately. However, if the crucible rotating speed changes to the extent that the convection intensity of the silicon melt is affected, the temperature at solid-liquid interface of the ingot and the silicon melt (the fluid level of the silicon melt) will be affected immediately. This means that the effect from the crucible rotating speed is more significant than that from the magnetic field strength. Therefore, in an embodiment, after the magnetic field strength of the magnetic field is changed, and as the detection of the changed diameter of the ingot is measured, the crucible rotating speed may be changed to meet the change of the ingot's diameter. Then the ingot's diameter may be controlled more accurately.

In an embodiment of the present invention, as and/or after the magnetic field strength of the horizontal magnetic field is increased, the crucible rotating speed is increased.

Because increasing the magnetic field strength of the horizontal magnetic field will reduce the convection in the silicon melt, at this time increasing the crucible rotating speed may facilitate the convection in the silicon melt to compensate the reduced convection in the silicon melt caused by the increasing the magnetic field strength and to further reduce the temperature fluctuation at the solid-liquid interface of the ingot and the silicon melt.

It can be understood by the person skilled in the art that it is only an example to increase the crucible rotating speed when increasing the magnetic field strength in the present embodiment, and it may be implemented by changing the crucible rotating speed (increasing or decreasing) when decreasing the magnetic field strength according to the present invention.

Specifically, in an embodiment of the present invention, as and/or after the magnetic field strength of the horizontal magnetic field is changed, the crucible rotating speed changing is periodic.

Because changing the magnetic field strength of the horizontal magnetic field on the silicon melt will result in periodic change of the temperature at the fluid level of the silicon melt underneath the solid-liquid interface, the crucible rotating speed changing may be periodic corresponding to the periodic change of the temperature at the fluid level of the silicon melt. Then, the convection in the silicon melt may be increased periodically to decrease the change of the temperature at the fluid level of the silicon melt caused by the changed magnetic field strength on the silicon melt to reduce the change of the ingot's diameter caused by the periodic change of the temperature at the fluid level of the silicon melt.

In an embodiment of the present invention, during each period of changing the crucible rotating speed, the crucible rotating speed changing is performed with steps of: increasing the crucible rotating speed from R0 to R1; maintaining the crucible rotating speed at R1 for a while; and decreasing the crucible rotating speed from R1 to R0, wherein R0 is an initial crucible rotating speed.

Referring to FIG. 4, which shows a plot diagram of variation of crucible rotating speed along with time according to an embodiment of the present invention. Vertical axis represents the crucible rotating speed (R), and horizontal axis represents time. It can be seen that the crucible rotating speed changing is periodic. In each period, the crucible rotating speed is increased from R0 to R1, and meanwhile the convection in the silicon melt is increased accordingly; then, the crucible rotating speed at R1 is maintained for a while to allow sufficient convection in the silicon melt; and finally, the crucible rotating speed is decreased from R1 to R0, and meanwhile the convection in the silicon melt is decreased accordingly. The periodic change of the convection in the silicon melt may be carried out with periodically increasing and decreasing the crucible rotating speed set with an initial crucible rotating speed R0. Therefore, the temperature at the solid-liquid interface of the ingot and the silicon melt may be changed periodically due to the periodical change of the convection in the silicon melt. Then, the effect of the periodic change of the temperature at the solid-liquid interface of the ingot and the silicon melt contributed by the decreased convection in the silicon melt generated by the applied magnetic field may be reduced.

In an embodiment of the present invention, the crucible rotating speed from R0 to R1 is increased linearly, and/or the crucible rotating speed from R1 to R0 is decreased linearly.

Referring to FIG. 4, during the crucible rotating speed periodically changing, in each period, the crucible rotating speed is increased linearly from R0 to R1 and then the crucible rotating speed is decreased linearly from R1 to R0. It is easy, efficient and applicable to linearly control the crucible rotating speed. It can be understood that controlling linearly is only an example and other style to control the rotating speed may be implemented according to the present invention.

Exemplarily, during the crucible rotating speed periodically changing, the crucible rotating speed may be changed within 100% R0-200% R0, in which R0 is an initial crucible rotating speed.

Referring to FIG. 4, during the crucible rotating speed periodically changing, the crucible rotating speed may be changed from R0 to R1, and R1 is 100%-200% greater than R0.

Increasing the crucible rotating speed will increase natural convection of the silicon melt to reduce temperature fluctuation at the solid-liquid interface of an ingot and the silicon melt. Then, the change of the ingot's diameter contributed by the temperature fluctuation at the solid-liquid interface of an ingot and the silicon melt may be reduced. At least two advantages may be provided by setting the crucible rotating speed changing within 100% R0-200% R0. One is to create sufficient effect on the change of the convection in the silicon melt, and the other is to avoid from excessive crucible rotating speed changing that may cause excessive change of the convection in the silicon melt to raise the temperature fluctuation at the fluid level.

Exemplarily, during the crucible rotating speed periodically changing, each period is within 1-10 min.

Referring to FIG. 4, the crucible rotating speed changing may occur from time 0, and a first period ends at time T1. T1 may be within 1-10 min. After the crucible rotating speed is changed from R0 to R1, it is maintained at R1 for a while and then changed from R1 to R0.

Further, exemplarily, during the crucible rotating speed periodically changing, a time interval exists between two consecutive periods.

When changing periodically, the convection in the silicon melt may be alleviated by setting a time interval existing between two consecutive periods to avoid from great temperature fluctuation at the fluid level caused by excessive convection. Exemplarily, the time interval may be within 1-2 min.

Further, exemplarily, during the crucible rotating speed periodically changing, a range of a number of changing the crucible rotating speed is within 5-50.

Specifically, in an example, the magnetic field may be increased from 1500 G to 4000 G and the crucible rotating speed 11 may be changed periodically according to technical requirements to form an ingot with a target diameter of 305 mm. When the magnetic field changes, the crucible rotating speed 11 periodically changing occurs. Specifically, in each period, the crucible rotating speed 11 changes as follows: increasing from 1.0 RPM to 2.5 RPM and keeping at 2.5 RPM in 3 min, and then decreasing to 1.0 RPM, and keeping at 1.0 RPM for 2 min, and then changing for next period until finishing 10th period. Through detection, periodically fluctuation of the ingot's diameter decreases at 50-100 mm and then becomes stable.

### Embodiment 2

The present invention further provides a crystal growth apparatus, comprising: a crucible, receiving silicon melt; a pulling device, pulling the silicon melt to form an ingot; a magnetic field applying device, applying a horizontal magnetic field to the silicon melt in the crucible and adjusting magnetic field strength of the magnetic field; a driving device, driving rotating of the crucible; and a controlling device, configured to perform the method illustrated in Embodiment 1 to control the way the driving device changing the crucible rotating speed according to magnetic field strength of the horizontal magnetic field applied by the magnetic field applying device.

Specifically, as or after the controlling device controls the magnetic field applying device to adjust the magnetic field strength, the controlling device further control the driving device to change the crucible rotating speed.

Because convection of the silicon melt, especially that at fluid level of the silicon melt, changes, generated by changed magnetic field strength of horizontal magnetic field applied to the silicon melt, temperature fluctuation occurs and then the diameter of the ingot changes. As and/or after changing magnetic field strength of the horizontal magnetic field applied to the silicon melt, controlled by the controlling device, the controlling device further control the driving device to change crucible rotating speed, and through the crucible rotating speed changing to change convection of the silicon melt, it may reduce the effect of the change of the magnetic field strength of the magnetic field on the convection of the silicon melt, and then avoid from temperature change at the fluid level of the silicon melt.

Referring to FIG. 1 showing a structural perspective view of a crystal growth apparatus according to an embodiment of the present invention, the growth apparatus comprises a furnace 1 inside of which a crucible is positioned. A heater 12 heating the crucible 11 is positioned outside the crucible 11. Silicon melt 13 is contained in the crucible 11.

Exemplarily, the crucible 11 is constructed by a graphite crucible and a quartz crucible set in the graphite crucible. The graphite crucible may be heated by the heater 12 to melt polysilicon material to form the silicon melt 13.

Referring to FIG. 1, the crystal growth apparatus according to the present invention comprises a pulling device 14 positioned at the top of the furnace 1. Driven by the pulling device 14, a crystal seed pulls an ingot 10 out of a fluid level of the silicon melt 13. Meanwhile, a heating screen is positioned around the ingot 10. As shown in FIG. 1, the heating screen may exemplarily comprise a draft tube 16 of barrel shape. On one hand, the draft tube 16 may isolate a surface of the ingot 10 from thermal radiations generated by the quartz crucible and the silicon melt 13, and increase cooling speed and axial temperature gradient of the ingot 10 to raise growth speed of the ingot 10. On the other hand, the heating screen may affect thermal field distribution of a surface of the silicon melt 13 to avoid from excessive difference of the axial temperature gradient between a center and a rim of the ingot 10, and ensure stable growth at an interface of the ingot 10 and the silicon melt 13. Meanwhile, the draft tube 16 may be used to pipeline inert gas introduced from the upper portion of the furnace 1. Then, the inert gas may pass the surface of the silicon melt 13 with a greater speed to control oxygen and impurity content in the ingot 10. During the growth of the ingot 10, moving with the pulling device 14, the ingot 10 moves upward and vertically, and passes through the draft tube 16.

To stabilize the growth of the ingot 10, a driving device 15 driving rotating of the crucible 11 is positioned at the bottom portion of the furnace 1. The driving device 15 drives the crucible 11 keep rotating during crystal pulling may reduce thermal asymmetry of the silicon melt 13 to grow the ingot 10 with a constant diameter.

To inhibit convection of the silicon melt 13, viscosity of the silicon melt 13 may be increased, and entrance of impurities from the quartz crucible, such as oxygen, carbon, aluminum, into the silicon melt 13 and further into the ingot may be reduced. Eventually, oxygen content of the grown ingot 10 may be controlled within a wide range from low to high to diminish growth striations. The crystal growth apparatus may further comprise a magnetic field applying device 17 to apply magnetic field to the silicon melt 13 in the crucible 11.

Magnetic field lines of the magnetic field applied by the magnetic field applying device 17 horizontally start from one end, pass the silicon melt 13 in the crucible 11, and then arrive an opposite end (referring to an arrow in dashed line in FIG. 1). Because the silicon melt 13 in fluid status has electric conductivity, under the magnetic field, Lorentz force generated in the silicon melt 13 inhibits natural convection in the silicon melt 13, which affects the diameter of the ingot 10 significantly.

In the crystal growth apparatus according to the present invention, a controlling device 8 is further comprised. The controlling device 8 controls adjustment of the driving device 15 on the crucible rotating speed 11 according to the magnetic field strength of the horizontal magnetic field applied by the magnetic field applying device 17.

In an embodiment of the present invention, the controlling device 18 controls the magnetic field applying device 17, i. e. the magnetic field strength of the horizontal magnetic field applied by the magnetic field applying device 17. Further, as or after the magnetic field strength of the horizontal magnetic field applied by the magnetic field applying device 17 changes, controlled by the controlling device 18, the controlling device 18 controls the adjustment of the driving device 15 on the crucible rotating speed 11.

Exemplarily, the crystal growth apparatus further comprises a diameter detector detecting the diameter of the ingot. The controlling device controls the driving of the driving device 15 on the crucible rotating speed 11 according to the detected ingot's diameter by the diameter detector.

As shown in FIG. 1, in the crystal growth apparatus according to the present invention, a diameter detector 19 is further comprised. The diameter detector 19 communicate with the controlling device 18. The controlling device 18 controls the driving of the driving device 15 on the crucible rotating speed 11 according to the detected ingot's diameter by the diameter detector 19.

Exemplarily, the diameter detector comprises an infrared sensor to detecting the position of a side wall of the ingot to measure the diameter of the ingot.

When the horizontal magnetic field changes, the change of the convection intensity of the silicon melt generated consequently will not affect the temperature of the fluid level of the silicon melt immediately. However, if the crucible rotating speed changes to the extent that the convection intensity of the silicon melt is affected, the temperature at the solid-liquid interface of the ingot and the silicon melt (the fluid level of the silicon melt) will be affected immediately. This means that the effect from the crucible rotating speed is more significant than that from the magnetic field strength. Therefore, in an embodiment, after the magnetic field strength of the magnetic field is changed, and as the detection of the changed diameter of the ingot is measured by the diameter detector, the crucible rotating speed changing may occur to meet the change of the ingot's diameter. Then the ingot's diameter may be controlled more accurately.

To sum up, according to the crystal growth method and crystal growth apparatus of the present invention, during the crystal growth, horizontal magnetic field is applied to the silicon melt in the crucible, and as and/or after a magnetic field strength of the horizontal magnetic field is changed, crucible rotating speed changing occurs. Because temperature fluctuation may easily occur at the solid-liquid interface of an ingot and the silicon melt as and/or after changing magnetic field strength of the horizontal magnetic field, through the crucible rotating speed changing to change forced convection of the silicon melt, the temperature fluctuation at solid-liquid interface, caused by the changing of the magnetic field strength, may be rapidly reduced to stabilize diameter of the ingot.

It is to be understood that these embodiments are not meant as limitations of the invention but merely exemplary descriptions of the invention with regard to certain specific embodiments. Indeed, different adaptations may be apparent to those skilled in the art without departing from the scope of the annexed claims. For instance, it is possible to add bus buffers on a specific data bus if it is necessary. Moreover, it is still possible to have a plurality of bus buffers cascaded in series.

What is claimed is:

1. A crystal growth method, comprising a step of:
maintaining rotating of a crucible and meanwhile applying a horizontal magnetic field to silicon melt in the crucible during crystal growth,
wherein as and/or after a magnetic field strength of the horizontal magnetic field is changed, crucible rotating speed is changed.

2. The crystal growth method according to claim 1, wherein after the horizontal magnetic field is changed and as a diameter of an ingot obtained from crystal growth changes, changing the crucible rotating speed.

3. The crystal growth method according to claim 1, further comprising:
as and/or after the magnetic field strength of the horizontal magnetic field is increased, increasing the crucible rotating speed.

4. The crystal growth method according to claim 3, wherein the crucible rotating speed changing is periodic.

5. The crystal growth method according to claim 4, wherein during each period of the crucible rotating speed changing, the method of the crucible rotating speed changing comprises:
increasing the crucible rotating speed from R0 to R1;
maintaining the crucible rotating speed at R1 for a while; and
decreasing the crucible rotating speed from R1 to R0, wherein R0 is an initial crucible rotating speed.

6. The crystal growth method according to claim 5, wherein the crucible rotating speed from R0 to R1 is increased linearly, and/or the crucible rotating speed from R1 to R0 is decreased linearly.

7. The crystal growth method according to claim 4, wherein during the period of the crucible rotating speed periodically changing, a crucible rotating speed maintaining time period is between each two consecutive periods.

8. The crystal growth method according to claim 4, wherein during the period of the crucible rotating speed periodically changing, the crucible rotating speed changing times is no less than 10 times.

9. A crystal growth apparatus, comprising:
a crucible, containing silicon melt;
a pulling device, pulling the silicon melt to form an ingot;
a magnetic field applying device, applying a horizontal magnetic field to the silicon melt in the crucible and adjusting magnetic field strength of the magnetic field;
a driving device, driving rotating of the crucible; and
a controlling device, configured to perform the steps as illustrated in the crystal growth method according to claim 1.

10. The crystal growth apparatus according to claim 9, further comprising:
a diameter detector, detecting an diameter of the ingot.
